(19) United States
(12) Patent Application Publication
(10) Pub. No.: US 2009/0015269 A1
(43) Pub. Date: Jan. 15, 2009

(54) Stray Capacitance Compensation for a Capacitive Sensor

(76) Inventors: Gino A. Pinto, Milford, MA (US); Justin M. Piccirillo, Uxbridge, MA (US); Michael J. Amirto, Windham, NH (US); Kevin M. Bourbeau, Pepperell, MA (US)

Correspondence Address: BEUSSE WOLTER SANKS MORA & MAIRE, P. A., 390 NORTH ORANGE AVENUE, SUITE 2500, ORLANDO, FL, 32801, US

(21) Appl. No.: 12/169,796

(22) Filed: Jul. 9, 2008

Related U.S. Application Data
(60) Provisional application No. 60/949,520, filed on Jul. 13, 2007.

(51) Int. Cl. G01R 27/26; G01L 9/12

(52) U.S. Cl. 324/684; 73/724

(57) ABSTRACT

A capacitive sensor (10) producing an output signal (V_{OUT}) that is insensitive to stray capacitance (C_{S}) caused by environmental and aging conditions. The sensor includes a sensing electrode (11) that exhibits a total capacitance that is responsive to both the measured process variable and to stray capacitance (C_{T}=C_{A}+C_{S}). The sensor also includes a reference electrode (19) that exhibits a stray capacitance (C_{S}′) essentially the same as that of the sensing electrode, but that is insensitive to the process variable. Balancing circuitry (29) provides an output signal that is responsive to the measured process variable and insensitive to the stray capacitance (V_{OUT}=C_{T}−C_{S}′). The reference electrode is manufactured of the same materials and dimensions as the sensing electrode and may be mounted in the sensor body proximate the sensing electrode.

### CROSS REFERENCE TO RELATED APPLICATIONS

This application claims benefit of the 13 Jul. 2007 filing date of U.S. provisional patent application No. 60/949,520.

### FIELD OF THE INVENTION

This invention relates generally to the field of sensors, and more specifically to capacitive sensors, and in particular to compensation for the effects of stray capacitance generated in a capacitive sensor by environmental and aging effects.

### BACKGROUND OF THE INVENTION

Capacitive sensors are known in the art for measuring process variables such as gauge pressure, differential pressure, absolute pressure, vacuum pressure, proximity, etc. Capacitive sensors function by measuring a change in the capacitance of a capacitor resulting from a change in the process variable. The change in capacitance is typically sensed through use of a discriminator circuit such as an AC Bridge Circuit. The change in capacitance is generally caused by a relative movement between two conductive elements of the capacitor driven by the change in the process variable. An exemplary prior art capacitive sensor is described in U.S. Pat. No. 5,939,639 titled “Pressure Transducer Housing with Barometric Pressure Isolation” incorporated by reference herein.

Capacitive sensors are subject to inaccuracies due to changes in capacitance resulting from variables other than the process variable being measured. For example, the dielectric constant of the structure of the capacitive sensor may change as a result of environmental effects, particularly temperature and humidity, both in the short term and in the long term (aging). It is known to compensate for such environmental effects by constructing a duel-electrode sensor wherein two active capacitance sensing electrodes are proximally or concentrically arranged to form two active sensors, wherein one of the sensors is configured to have a greater sensitivity to changes in the sensed process variable. The difference in the two signals is then processed as being indicative of the process variable value and is relatively insensitive to any environmental/aging effects. One such design is described in U.S. Pat. No. 6,105,436 titled “Capacitive Pressure Transducer with Improved Electrode Support” also incorporated by reference herein. Unfortunately, such dual electrode sensors are relatively complicated to manufacture and require tight tolerances, and they tend to be more expensive than single electrode capacitive sensors.

### BRIEF DESCRIPTION OF THE DRAWINGS

The present invention is explained in the following description in view of the drawings that show:

FIG. 1 is a partial cross-sectional illustration of a single electrode differential pressure sensor including an integral reference capacitor.

FIG. 2 is a schematic representation of the capacitances of the sensor of FIG. 1.

FIG. 3 is a partial cross-sectional illustration of a single electrode differential pressure sensor including a discrete reference capacitor.

### DETAILED DESCRIPTION OF THE INVENTION

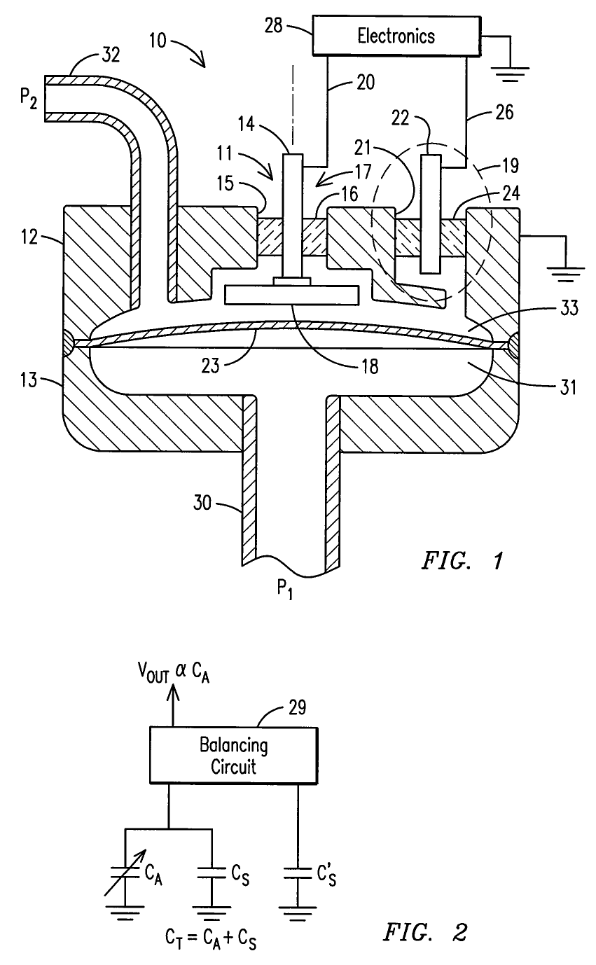

FIG. 1 illustrates a single electrode differential pressure sensor 10 that is compensated for environmentally induced stray capacitance inaccuracies. The sensor includes a lower sensor body 13 in fluid communication with a process pressure port 30 such that a process pressure is present in a process pressure chamber 31. An upper sensor body 12 is in fluid communication with a reference pressure port 32 such that a reference pressure is present in a reference pressure chamber 33. The process pressure chamber 31 is separated from the reference pressure chamber 33 by a diaphragm 23 such that the diaphragm is displaced in response to relative changes in the pressure in the two chambers 31, 33. The diaphragm 12 may be made of an electrically conductive material or may be a non-conductive material having a conductive coating.

A sensing electrode 11 is disposed in a first opening (or feed through) 15 in the upper sensor body 12. The sensing electrode 11 includes an active electrode area 18 oriented generally parallel to the diaphragm, and a sensing electrode post 14 connected to the active electrode area 18 and extending though the first opening 15. The sensing electrode 11 is supported within and electrically isolated from the upper sensor body 12 by a sensing electrode insulator 16, which may be a glass, glass-ceramic, ceramic, plastic, epoxy, or other suitable electrically insulating material. The sensing electrode 11 is connected by suitable sensing electrode lead 20 to circuitry 28. The sensing electrode 11 cooperates with the diaphragm 12 to function as a sensing capacitor 17 for circuitry 28, with the total capacitance value CT of the capacitor 17 being directly responsive to the position of the diaphragm 12, and therefore responsive to the fluid pressure in the first chamber 31.

The sensor 10 also innovatively includes a reference electrode 19 which is not responsive to the pressure differential between the chambers 31, 33. Reference electrode 19 is formed to be like the sensing electrode 11 with regard to its stray capacitance, that is, to closely match or to be identical to the sensing electrode 11 with regard to those features that may affect the response of the capacitance of the respective electrodes to various short term and aging environmental effects. In particular, reference electrode 19 is disposed in a second opening 21 in upper sensor body 12 having the same diameter as the first opening 15. Further, the reference electrode 19 includes a reference electrode post 22 and a reference electrode insulator 24 that are geometrically matched to, and that are formed of the same materials as, the sensing electrode post 14 and sensing electrode insulator 16 respectively. The present inventors have recognized that a significant portion of the stray capacitance C_{S} of sensing electrode 11 is generated by changes in the capacitive response of the structure of the sensing electrode 11. For example, changes in the dielectric constant of the electrode insulator over time or sub-micron dimensional changes may contribute a significant amount of variability into the total capacitance of the electrode. Accordingly, when the reference electrode 19 is connected to the circuitry 28 by reference electrode lead 26, appropriate signal processing techniques may be used to compensate for the stray capacitance C_{S} of the sensing electrode 11 by using the stray capacitance value C_{S}′ of the reference electrode 19. This is possible because the reference electrode 19 will exhibit environmentally induced stray capacitance changes that are the same as or very close to those of sensing electrode 11 while at the same time being insensitive to changes in the process variable, since reference electrode 19 does not include an active electrode area equivalent to area 18 of the sensing electrode 11, and therefore its capacitance does not change as a function of the position of the diaphragm 23.

FIG. 2 illustrates how circuitry 28 may process inputs from the sensing electrode 11 and reference electrode 19 to produce an output signal such as S_{OUT} (typically a voltage signal V_{OUT}, although other types of output signals may be envisioned) that is compensated for stray capacitance C_{S} of sensing capacitor 17. In particular, the total capacitance C_{T} of sensing capacitor 11 includes the active capacitance C_{A} responsive to the process fluid pressure in first chamber 31 plus the stray capacitance C_{S}. The reference electrode 19 exhibits a capacitance that is essentially insensitive to changes in the process fluid pressure but that does exhibit its own stray capacitance C_{S}′ due to the same short and long term environmental effects that affect the sensing electrode 11. Because the sensing electrode 19 and the reference electrode 11 are constructed to be substantially similar, they exhibit a desired degree of similarity in stray capacitance response. When C′_{S} is essentially the same as C_{S}, a balancing circuit 29 of circuitry 28 may be used to take a difference between C_{T} and C_{S}′ i.e., (C_{A}+C_{S})−C_{S}′=C_{A}, to produce output signal Vₒᵤₜ which is proportional to C_{A} and independent of Cₛ. The present inventors have recognized that the stray capacitance variations in such electrodes are responsive primarily to the dimensions and materials of construction of the electrode post and insulator and to the stress state in the insulator, thus the similarity of these features between the sensing electrode 11 and reference electrode 19 are important.

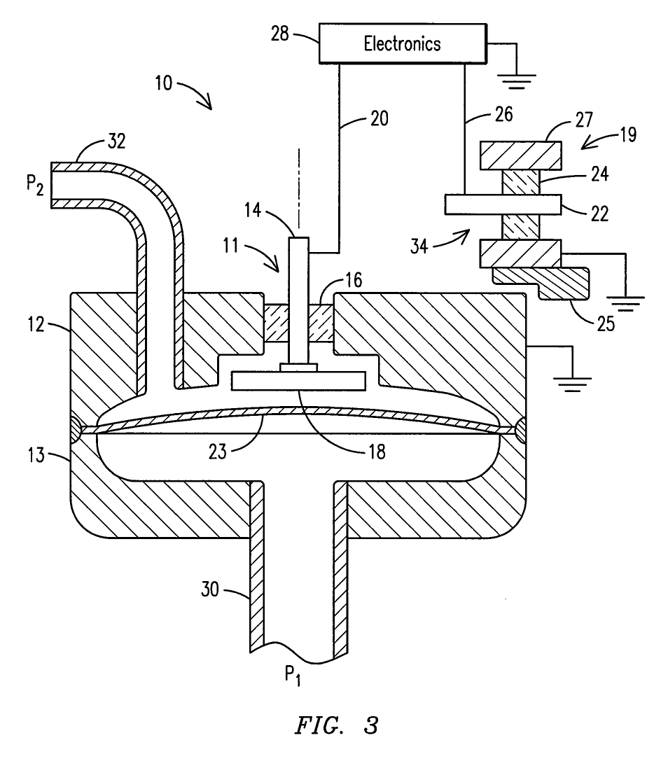

FIG. 3 illustrates another embodiment of the present invention where a discrete (i.e. separate from the sensor body) reference electrode 34 is used in lieu of the integrally formed reference electrode 19 of FIG. 1. The discrete reference electrode 34 includes a reference electrode post 22 and reference electrode insulator 24 that are essentially the same as those of the sensing electrode 11. In this embodiment, the sensing electrode insulator 24 is disposed in an outer shell 27 preferable formed of the same material as the upper sensor body 12 and having a thickness adequate to exert mechanical stresses on the reference electrode insulator 24 that are similar to those exerted on the sensing electrode insulator 16, since the stress state of the insulator will affect the stray capacitance value. Alternatively, outer shell 27 can be formed with alternate material having alternate mechanical properties (e.g., different modulus and/or yield strength) and an appropriate thickness that when formed induces mechanical stresses on the reference electrode insulator 24 that are similar to those exerted on the sensing electrode insulator 16. The discrete reference electrode 34 is supported by a support structure 25 such as a bracket attached to the sensor 10. The discrete reference electrode 34 should be exposed to the same environmental conditions as the sensing electrode 11. In other embodiments the discrete reference electrode 34 may be located at any desired location, even away from the sensor 10, provided that its stray capacitance is sufficiently correlated to the stray capacitance of the sensing electrode 11 to achieve a desired degree of compensation. For example, in one embodiment, the present invention makes it possible to reduce the drift in sensor output V_{OUT} due to temperature aging from about 0.2% to about 0.03%.

It may be appreciated that the correlation of the stray capacitance of the sensing electrode and the reference electrode is responsive to manufacturing variables such as dimensions, materials of construction, surface finish, etc. The required similarity between the sensing and reference electrodes may vary for different applications, but generally it is desired to manufacture both parts from the same materials, using the same procedures and manufacturing tolerances to the extent practical. Slight differences between the sensing and reference electrodes may affect the overall improvement in accuracy that can be achieved without departing from the innovative concept of the present invention.

While various embodiments of the present invention have been shown and described herein, it will be obvious that such embodiments are provided by way of example only. Numerous variations, changes and substitutions may be made without departing from the invention herein. Accordingly, it is intended that the invention be limited only by the spirit and scope of the appended claims.

The invention claimed is:

1. A capacitive sensor comprising:
a sensing electrode exhibiting a total capacitance (C_{T}) including an active capacitance (C_{A}) responsive to a measured process variable and a stray capacitance (C_{S}) responsive to an environmental condition;
a reference electrode exhibiting a stray capacitance (C_{S}′) responsive to the environmental condition and being unresponsive to the process variable; and
circuitry comprising the sensing electrode and the reference electrode for producing an output signal (S_{OUT}) responsive to the measured process variable and independent of the environmental condition (C_{T}−C_{S}′).

2. The sensor of claim 1, wherein the reference electrode comprises a reference electrode post and reference electrode insulator formed to have dimensions and materials of construction the same as those of a respective sensing electrode post and sensing electrode insulator of the sensing electrode.

3. The sensor of claim 2, wherein the sensing electrode and the reference electrode are disposed in respective equally-sized openings in a body of the sensor.

4. The sensor of claim 2, wherein the sensing electrode is disposed in an opening in a body of the sensor and the reference electrode is disposed in a support structure other than the body of the sensor formed of the same material as the body of the sensor.

5. The sensor of claim 2, wherein the sensing electrode is disposed in an opening in a body of the sensor and the reference electrode is disposed in a support structure other than the body of the sensor formed to impose mechanical stresses on the reference electrode insulator that correspond to stresses imposed on the sensing electrode insulator by the body of the sensor.

6. A capacitive sensor comprising:
a first sensor body member comprising a process pressure port and partially defining a first chamber;
a second sensor body member comprising a reference pressure port and partially defining a second chamber;
a diaphragm disposed between the first and second body members and displaceable in response to relative changes in pressures within the first and second chambers;
a sensing electrode disposed through a first opening in one of the body members and cooperating with the diaphragm to form a capacitor exhibiting a total capacitance responsive to a position of the diaphragm and to an environmental effect (C_{T}=C_{A}+C_{S});
a reference electrode disposed through a second opening in one of the body members and forming a capacitor exhibiting a total capacitance responsive to the environmental effect and non-responsive to the position of the diaphragm (C_{S}′); and
balancing circuitry comprising the sensing electrode and the reference electrode for generating an output signal (V_{OUT}=Ct−C_{S}′).

7. The sensor of claim 6, further comprising:
the sensing electrode comprising a sensing electrode post and a sensing electrode insulator surrounding the sensing electrode post to insulate the sensing electrode post from the respective body member; and
the reference electrode comprising a reference electrode post and a reference electrode insulator surrounding the reference electrode post to insulate the reference electrode post from the respective body member;
wherein the sensing electrode post and reference electrode post are made of like dimensions and materials; and
wherein the sensing electrode insulator and reference electrode insulator are made of like dimensions and materials.

8. A capacitive sensor for measuring a process variable comprising:
a sensing electrode comprising a sensing electrode post, a sensing electrode insulator for electrically insulating the sensing electrode post from a body of the sensor, and an active electrode area in a capacitive relationship with a diaphragm of the sensor that is responsive to the process variable;
a reference electrode formed of like materials and dimensions as the sensing electrode but lacking an active electrode area in capacitive relationship with the diaphragm; and
circuitry generating an output signal indicative of the process variable and responsive to a difference between capacitance values of the sensing electrode and the reference electrode.

9. The capacitive sensor of claim 8, wherein the sensing electrode is disposed through a first opening in the body of the sensor and the reference electrode is disposed through a second opening in the body of the sensor.

10. The capacitive sensor of claim 8, wherein the sensing electrode is disposed through an opening in the body of the sensor and the reference electrode is disposed through an opening in a shell member separate from the body of the sensor formed to impose mechanical stresses on the reference electrode that correspond to stresses imposed on the sensing electrode by the body of the sensor.
